(19) United States
(12) Patent Application Publication
(10) Pub. No.: US 2020/0333284 A1
(43) Pub. Date: Oct. 22, 2020

(54) HIGH SURFACE AREA ELECTRODE FOR ELECTROCHEMICAL SENSOR

(71) Applicant: Honeywell International Inc., Morris Plains, NJ (US)

(72) Inventors: Scott Edward Beck, Murphy, TX (US); Philip C. Foster, Murphy, TX (US); Yong-Fa Wang, Frisco, TX (US)

(21) Appl. No.: 16/388,584

(22) Filed: Apr. 18, 2019

(51) Int. Cl. G01N 27/407; G01N 27/404; G01N 27/30; B81C 1/00

(52) U.S. Cl. CPC G01N 27/4071; G01N 27/404; G01N 27/307; B81B 2203/04; G01N 27/4073; B81C 1/00166; G01N 27/4076

(57) ABSTRACT

Apparatus and associated fabrication methods related to a micro-electro-mechanical system (MEMS) based electrochemical sensor include an electrolyte contacting two or more electrode(s) arranged on a substrate, and a high surface area electrode disposed on top of at least a sensing electrode of the sensor. Various embodiments of the high surface area electrode may increase a current or potential produced by the MEMS-based electrochemical sensor in response to one or more targeted chemical species or gases, and allow fabrication and operation of smaller electrochemical sensors. The electrodes may be electrically coupled to control and measurement circuitry. In some examples, the control and measurement circuitry may be formed on the same substrate.

### TECHNICAL FIELD

The present disclosure relates generally to electrochemical sensors. In particular, various embodiments of electrochemical sensors are described having a high-surface area electrode.

### BACKGROUND

Electrochemical sensors are devices that interact with selected chemical species and transduce the chemical energy of the interaction into a signal that can be detected and analyzed to provide information of the selected chemical species. For example, electrochemical gas sensors can measure the concentration of a target gas by oxidizing or reducing the target gas at an electrode and measuring the resulting current. Sensors of this type often contain one or more electrodes in contact with an electrolyte. When gas interacts with an electrode, the electrochemical reaction may result in an electric current that passes through an external circuit for intensity measurement.

Electrochemical sensors may be employed, as an example, for environmental monitoring. For example, the sensors may monitor air quality, detect the presence of air pollution, and/or determine the composition of sources of air pollution. Electrochemical sensors may also be employed for personal safety in settings where dangerous chemicals may suddenly exist. The sensors may trigger audible alarms and/or visible warning lights. Some electrochemical sensors require no system power to operate (i.e. requiring no bias voltage across electrodes of the sensors), and are thus well-suited for high-volume commercial battery-powered applications.

More recently, MEMS electrochemical sensors have been developed. However, because electrochemical sensors of this type are smaller, the current produced by the reaction of the analyte (e.g., the chemical species of interest) is also smaller. In particular, MEMS electrochemical sensors typically include planar electrodes on the order of less than 50 square mm and produce current in the nA range. The inventors have recognized that this impacts the ability of MEMS electrochemical sensors to reliably measure and distinguish a large range of chemical concentrations. Accordingly, there is a need in the art for MEMS electrochemical sensors with improved sensing ability and corresponding methods for manufacturing the same.

### BRIEF SUMMARY

Embodiments of the present invention include apparatus and associated fabrication methods related to an electrochemical sensor (e.g., a micro-electro-mechanical system (MEMS)-based electrochemical sensor).

In various embodiments, the electrochemical sensor includes a substrate, a plurality of electrodes disposed on the substrate, a dielectric layer disposed on the substrate such that at least a portion of the plurality of electrodes are not in contact with the substrate, a high surface area electrode disposed on the substrate and/or the dielectric layer, and an electrolyte disposed over at least a portion of each of the high surface area electrode and the plurality of electrodes.

In some embodiments, the high surface area electrode comprises a porous material. For example, the high surface electrode may comprise a fractal metal electrode, such as a fractal platinum electrode. In various embodiments, the high surface area electrode may be formed by electrochemical deposition. In some embodiments, the high surface area electrode is formed in a metal solvent mixture or with a particle-free complex conductive ink.

In various embodiments, the plurality of electrodes may include a counter electrode and a reference electrode. In some embodiments, the plurality of electrodes may include a sensing electrode a sensing electrode disposed on the substrate and/or the dielectric layer and between the high surface area electrode and the substrate and/or the dielectric layer.

In various embodiments, the high surface area electrode may comprise at least one of gold, platinum, palladium, rhodium, or ruthenium. In some embodiments, the substrate comprises at least one of a porous silicon substrate, a porous alumina substrate, or a silicon substrate with micro-channels.

According to various embodiments, a method of forming an electrochemical sensor is also provided. In some embodiments, the method of forming the electrochemical sensor may include the steps of: forming a plurality of electrodes on a substrate, disposing a dielectric layer on the substrate such that at least a portion of the plurality of electrodes are not in contact with the substrate, disposing a high surface area electrode on the substrate and/or the dielectric layer, and disposing an electrolyte over at least a portion of each of the high surface area electrode and the plurality of electrodes.

In various method embodiments, the high surface area electrode may be formed from a porous material. In some embodiments, the high surface area electrode may be a fractal metal electrode, such as a fractal platinum electrode.

In some method embodiments, the high surface area electrode is formed in by electrochemical deposition. In some embodiments, the high surface area electrode is formed by printing one of an ink in a metal solvent mixture or a particle-free complex conductive ink.

In some method embodiments, the plurality of electrodes comprise a counter electrode and a reference electrode. In some embodiments, the plurality of electrodes comprise a sensing electrode disposed on the substrate and/or the dielectric layer and between the high surface area electrode and the substrate and/or the dielectric layer.

In some method embodiments, the high surface area electrode comprises at least one of gold, platinum, palladium, rhodium, or ruthenium. In some embodiments, the substrate comprises at least one of a porous silicon substrate, a porous alumina substrate, or a silicon substrate with micro-channels.

### BRIEF DESCRIPTION OF THE DRAWINGS

FIG. 1 depicts a cross-sectional elevation view of an exemplary MEMS-based electrochemical sensor according to an embodiment of the present invention.

FIG. 2 illustrates a first step of a method of fabricating a MEMS-based electrochemical sensor in which an oxidized substrate is provided according to one embodiment.

FIG. 3 illustrates a second step of a method of fabricating a MEMS-based electrochemical sensor in which a plurality of electrodes are deposited according to one embodiment.

FIG. 4 illustrates a third step of a method of fabricating a MEMS-based electrochemical sensor in which a dielectric layer is coated and patterned according to one embodiment.

FIG. 5 illustrates a fourth step of a method of fabricating a MEMS-based electrochemical sensor in which a high surface area electrode is deposited and defined according to one embodiment.

FIG. 6 illustrates a fifth step of a method of fabricating a MEMS-based electrochemical sensor in which an electrolyte is disposed according to one embodiment.

FIG. 7 depicts a cross-sectional elevation view of another exemplary MEMS-based electrochemical sensor according to an embodiment of the present invention.

FIG. 8 illustrates a MEMS-based electrochemical sensor on a circuit board according to an embodiment of the present invention.

### DETAILED DESCRIPTION OF ILLUSTRATIVE EMBODIMENTS

Various embodiments of MEMS-based electrochemical sensors are described herein. According to various embodiments, a high surface area electrode is provided and disposed on top of a sensing electrode of the MEMS-based electrochemical sensor. As detailed herein, the high surface area electrode has the advantage of increasing a current or potential produced by the MEMS-based electrochemical sensor in response to one or more targeted chemical species or gases. Furthermore, the use of the high surface area electrode allows fabrication and operation of smaller electrochemical sensors. The smaller size of the MEMS-based electrochemical sensor described herein also reduces the packaged power requirements.

For these reasons, the MEMS-based electrochemical sensor may have a low-cost and small footprint. As a result, the electrochemical sensors described herein can be more effectively integrated with a mobile device or Internet of Things (IoT) apparatus to detect one or more chemical species. Indeed, the various technical advantages of the high surface area electrode enable a wide range of applications for the MEMS-based electrochemical sensor, including environmental monitoring, air quality monitoring, and personal protection, among others

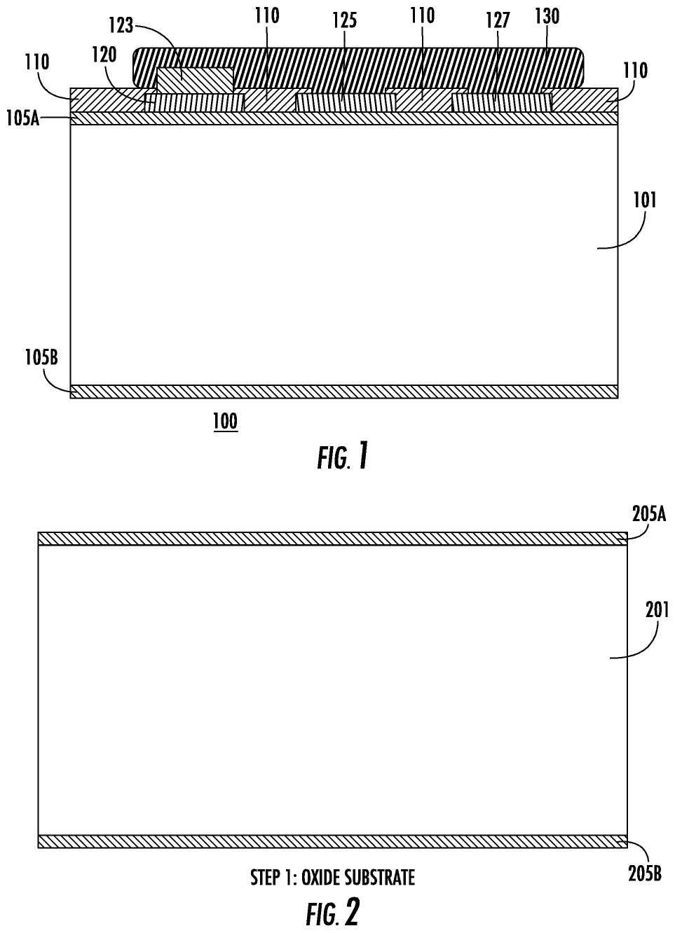

FIG. 1 depicts a cross-sectional elevation view of an exemplary MEMS-based electrochemical sensor 100 according to one embodiment. In the illustrated embodiment, the sensor 100 comprises a substrate 101 having a plurality of electrodes. The plurality of electrodes include a sensing electrode 120, a counter electrode 125, and a reference electrode 127. The electrodes 120, 125, 127 are disposed on a first insulator layer 105A formed on a top surface of the substrate 101. A second insulator layer 105B may be disposed on the opposite side of the substrate 101. Additionally, as described in greater detail herein, a high surface area electrode 123 is formed on an upper surface of the sensing electrode 120.

The electrochemical sensor 100 further comprises an electrolyte 130, which is disposed over at least a portion of each electrode 123, 125, 127. A dielectric layer 110 is also provided and formed over at least a portion of the top surface of the first insulator layer 105A (e.g., the portion of the first insulator layer 105A that is not covered by the plurality of electrodes). In some embodiments, the dielectric layer 110 may also cover a portion of each of the electrodes 120, 125, 127.

According to various embodiments, the substrate 101 may be formed from silicon, which is very well-characterized and for which equipment and processes are well-established. In some implementations, the substrate may comprise silicon nitride, silicon oxide, a doped silicon (e.g. doped with boron, arsenic, phosphorous, or antimony) or any combination thereof.

In various other embodiments, the substrate 101 may comprise semiconductors, plastics, or ceramics. For example, the substrate may be a porous alumina (Al₂O₃) substrate, a porous silica (SiO₂) substrate, a porous silicon substrate, a silicon substrate with micro-channels, or a polytetrafluoroethylene (PTFE) substrate.

According to various embodiments, the first insulator layer 105A is grown on top of the substrate 101. The insulator layer may be, for example, an oxide layer. In some alternative embodiments, the first insulator layer 105A may be a polymeric or glass insulator layer printed on top of the substrate 101. In various embodiments, the insulator layers 105A and 105B may be deposited by any suitable method (e.g., chemical vapor deposition, sputtering, and the like).

The second insulator layer 105B can be formed using the same method as that of the first insulator layer 105A. In other embodiments, the MEMS-based electrochemical sensor 100 may be formed on a ceramic or other insulating substrate. The sensor 100 can be disposed directly on the insulating substrate without the insulator layers 105A and 105B.

In some embodiments, the plurality of electrodes 120, 125, 127 are deposited on top of the first insulator layer 105A. The sensing electrode 120, the counter electrode 125, and the reference electrode 127 can be arranged in a co-planar, non-overlapping arrangement on the surface of the first insulator layer 105A. While the MEMS-based electrochemical sensor shown in FIG. 1 includes three electrodes, various other embodiments of the MEMS-based electrochemical sensor 100 can also be used with only two electrodes (e.g., the sensing electrode 120 and the counter electrode 125).

In certain embodiments, the electrochemical sensor 100 includes a sensing electrode 120 and counter electrode 125. In such embodiments, the reference electrode 127 may be excluded from the sensor 100.

In other embodiments, four or more electrodes may be present. For example, two or more sensing electrodes may be present to enable the detection of more than one target chemical species or gases. Additionally, four or more electrodes may be present to enable diagnostic tests to be conducted during operation of the MEMS-based electrochemical sensor 100, continuously, periodically, or aperiodically. For some other implementations, bond pads and pads for the electrical connections for the electrochemical depositions of the platinum group metals and gold may be present. In some contexts, the sensing electrode 120 may also be referred to as a working electrode.

When semiconductor manufacturing techniques are used to form the MEMS-based sensor 100, the electrodes 120, 125, 127 may comprise materials capable of being deposited by such processes as thermal deposition, sputtering, chemical vapor deposition, electrodeposition, or the like. For example, the electrodes 120, 125, 127 may comprise materials capable of being electrodeposited and etched to form the individual electrodes.

In some embodiments, the sensing electrode 120, the counter electrode 125, and the reference electrode 127, are printed on top of the first insulator layer 105A. For example, in embodiments where printing technologies are used to manufacture the MEMS-based electrochemical sensor 100, the electrodes 120, 125, 127 can be printed using conductive inks. The conductive inks can be particle-free metal complex inks. Alternatively, the conductive inks may contain metal nanoparticles, such as gold or silver nanoparticles for example, dispensed in liquid solvent. Substrate heating may be necessary after deposition to evaporate the liquid so that only the solid conductive material remains. Sintering at an elevated temperature for an extended duration may be necessary to improve the conductivity of the printed electrodes.

The composition, size, and configuration of the electrodes 120, 125, 127 can depend on the specific species of targeted chemicals or gases being detected by the MEMS-based electrochemical sensor 100. In some examples, the size of each of the plurality of electrodes can be on the order less than 50 square mm.

The electrodes 120, 125, 127 generally allow for various reactions to take place to allow a current or potential to develop in response to the presence of one or more targeted chemical species or gases. The resulting signal may then allow for the concentration of the targeted chemical species or gases and/or other information, such as whether a targeted chemical species or gas exists, to be determined. The electrodes can comprise a reactive material suitable for carrying out a desired reaction. For example, the sensing electrode 120 and/or the counter electrode 125 can be formed of one or more metals or metal oxides such as copper, silver, gold, nickel, platinum, palladium, rhodium, ruthenium, combinations thereof, alloys thereof, and/or oxides thereof. The reference electrode 127 can comprise any of the materials listed for the sensing electrode 120 and/or the counter electrode 125, though the reference electrode 127 may generally be inert to the materials in the electrolyte in order to provide a reference potential for the sensor. For example, the reference can contain a noble metal such as platinum or gold.

In various embodiments, the dielectric layer 110 can be formed over at least a portion of the top surface of the first insulator layer 105A that is not covered by the plurality of electrodes. For example, the dielectric layer 110 may be formed between the electrodes 120, 125, 127. The dielectric layer 110 may also cover a portion of each of the electrodes 120, 125, 127. Common dielectric materials such as silicon oxide, silicon nitride, or a combination thereof may be employed. In some alternative embodiments, the dielectric layer 110 may be polymeric insulator printed on top of the first insulator layer 105A.

According to various embodiments, the high surface area electrode 123 is formed on top of the sensing electrode 120 to increase the current or potential produced by the MEMS-based electrochemical sensor 100 in response to the presence of one or more targeted chemical species or gases. In various embodiments, high surface area electrode 123 is formed from a high-surface area material, such as a generally porous material or a material with complex topology, that increases the surface area of the electrode in comparison to conventional electrode material.

For example, in embodiments in which the high-surface area electrode 123 is formed from a porous material, the high surface area electrode 123 can comprise fractal or granulated metal electrodes. For example, the high surface area electrode 123 can comprise fractal or granulated gold electrodes, fractal or granulated platinum electrodes, or combination thereof. For some applications, platinum is preferred—due to its catalytic properties. In some embodiments, the fractal metal electrodes in the high surface area electrode 123 can be fabricated using electrochemical deposition of platinum or gold. In some alternative embodiments, the high surface area metal electrodes in the high surface area electrode 123 can be formed by printing technologies using specially-formulated inks in a solvent mixture. The solvent mixture can be a solution or suspension containing a metal pre-cursor. Printing of the solution can be followed by a conversion process to produce the high surface area electrode 123.

In other embodiments in which the high-surface area electrode 123 is formed from a material having a complex topology, the high-surface area electrode 123 may be provided with non-planar surfaces. For example, in one embodiment, the high-surface area electrode 123 may be provided with a plurality of outwardly extending pillars (e.g., having a surface generally resembling a stalagmite formation). In other embodiments, the high-surface area electrode 123 may be provided with a fern leaf structure. In various embodiments, the high-surface area electrode 123 formed with a complex topology is constructed with a generally porous material, such as those described herein.

In some embodiments, the high surface electrode 123 may comprise a single monolithic material configured to serve as a sensing electrode (e.g., as opposed to a two-material combination with a high surface area material on top, as depicted in FIG. 1).

In some implementations, the electrolyte 130 can be disposed over at least a portion of each electrode 125, 127 and the high surface area electrode 123. In some embodiments, the electrolyte 130 may be a solid polymer electrolyte. Solid polymer electrolytes may resist evaporation which may advantageously produce a long-life product. In some implementations, the electrolyte 130 may be in a liquid or gel form. In some examples, the electrolyte 130 can be formed via a variety of printing technologies, including but not limited to ink jet printing, aerosol jet printing, or screen printing. Alternatively, the electrolyte can be added with a drop dispenser. After the electrolyte 130 is formed, or before depending on the electrolyte, the substrate or wafer can undergo singulation and subsequently be introduced into final packaging. The packaging of the sensor depends largely on the final system needs and constraints. In some alternative examples, the electrolyte 130 can be added during the packaging process after the substrate wafer of the MEMS-based sensor 100 is singulated.

In the MEMS-based electrochemical sensor 100 as shown in FIG. 1, the electrode 123 increases the surface area where the chemical species or gas, the sensing electrode, and the electrolyte are all in contact, sometimes called the “triple point”. As a result of the increased surface area which enhances electrochemical activity, the current or potential produced by the MEMS-based electrochemical sensor 100 in response to the targeted chemical species or gas is increased. This improved response allows fabrication and operation of smaller electrochemical sensors that are currently commercially unavailable.

According to various embodiments, the MEMS-based electrochemical sensor 100 may have dimensions (e.g., length and/or width and/or thickness) on the scale of 1 mm×1 mm×1 mm to 10 mm×10 mm×10 mm. Due to the small size of the MEMS-based electrochemical sensor 100, one or more sensors can be integrated with a mobile device or Internet of Things (IoT) apparatus to detect one or more chemical species, thereby enabling a wide range of applications.

As one example, the MEMS-based electrochemical sensor 100 may be integrated with a mobile device to measure air quality. For example, the mobile device user may decide to move indoors if the pollution level is found too high. In another illustrative example, a miner may carry his mobile device (e.g., cell phone, tablet, watch, laptop) into a mine. The mobile device may contain a MEMS-based electrochemical sensor that is designed to detect one or more relevant gases (e.g., oxygen, carbon monoxide, hydrogen sulfide). The mobile device may alert the miner when one or more of those gases cross a predetermined threshold. Accordingly, the MEMS-based electrochemical sensor 100 may protect the miner's health.

In aerospace applications, users may monitor, for example, oxygen levels on an airplane. In some examples, oxygen levels may also be monitored by individuals who are prescribed oxygen therapy, such as individuals with chronic obstructive pulmonary disease (COPD). In such examples, the individuals may need to be administered oxygen in situations where the oxygen levels decrease below a predetermined threshold.

In various home use embodiments, due to the small-size and low-cost of the MEMS-based electrochemical sensor 100, homeowners may purchase in-home electrochemical sensors economically. The economical aspect of the MEMS-based electrochemical sensor 100 may allow the homeowner to advantageously deploy the MEMS-based electrochemical sensors 100 in more places and/or may bring multiple gas sensing (e.g., CO, hydrogen sulfide (H₂S), nitrogen oxides (NOₓ), sulfur oxides (SOₓ), volatile organic compounds (VOCs)) within an average homeowner's budget.

FIGS. 2-6 show a method of fabricating a MEMS-based electrochemical sensor 100 according to an embodiment of the present invention. FIG. 2 illustrates a first step in the exemplary fabrication method. In Step 1, oxide layers 205A and 205B are first formed on both sides of a substrate 201 to provide insulation for the substrate.

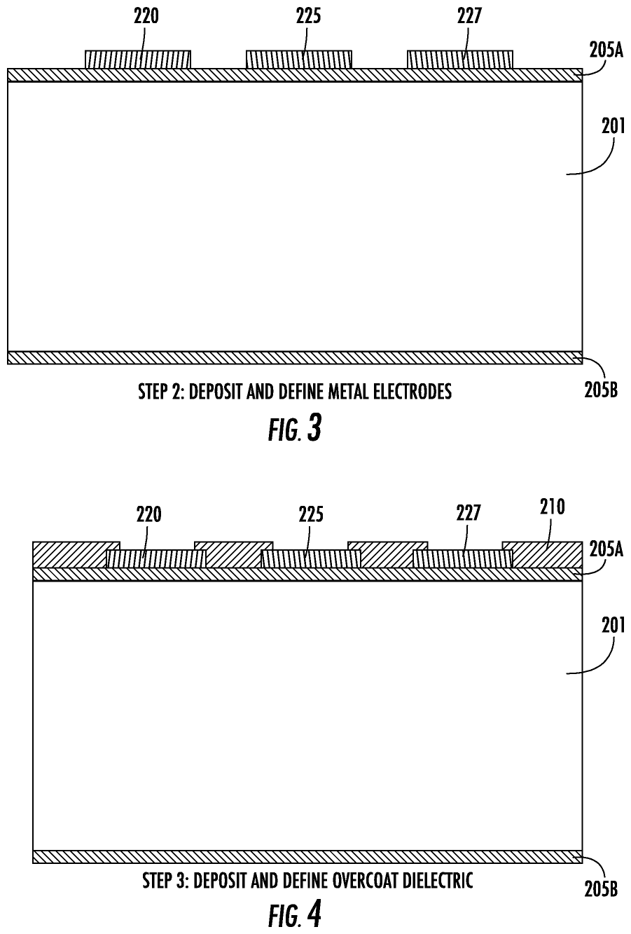

FIG. 3 illustrates a second step in the exemplary fabrication method. In Step 2, a plurality of electrodes are disposed over the substrate. In particular, a sensing electrode 220, a counter electrode 225, and a reference electrode 227 are disposed on a top surface of the oxide layer 205A. This can be accomplished using suitable techniques, such as thermal deposition, sputtering, chemical vapor deposition, etching, electrodeposition, or the like.

FIG. 4 illustrates a third step in the exemplary fabrication method. In Step 3, a dielectric layer 210 is coated over the top surface of the plurality of electrodes 220, 225, 227 and a portion of the top surface of the first insulator layer 105A that is not covered by the plurality of electrodes. The dielectric layer 210 is then patterned to expose at least a portion of the plurality of electrodes and/or other areas (e.g., bond pads and pads for electrical connections). The dielectric material may be, for example, silicon oxide, silicon nitride, a polymer, or a combination thereof. The dielectric layer 210 may be deposited using plasma-enhanced chemical vapor deposition (PECVD) or spin coating, or spray coating, or jet printing, describing various processing methods for depositing and or patterning a thin dielectric film.

FIG. 5 illustrates a fourth step in the exemplary fabrication method. In Step 4, the high surface area electrode 223 is deposited and defined. For example, in one embodiment, a photoresist layer may be deposited over the dielectric layer 210 and the electrodes 225, 227. When the photoresist layer is deposited, it may be patterned so as to leave the surface of the sensing electrode 220 exposed. The high surface area electrode 223 is then deposited on top of the sensing electrode 220. This step may be accomplished, for example, using an electrochemical deposition method (e.g., of platinum or gold). The high surface area electrode 223 may be formed from any of the suitable high surface area materials discussed herein. In various other embodiments, the fourth step could be performed by etching, screen-printing, or other common semiconductor fabrication techniques.

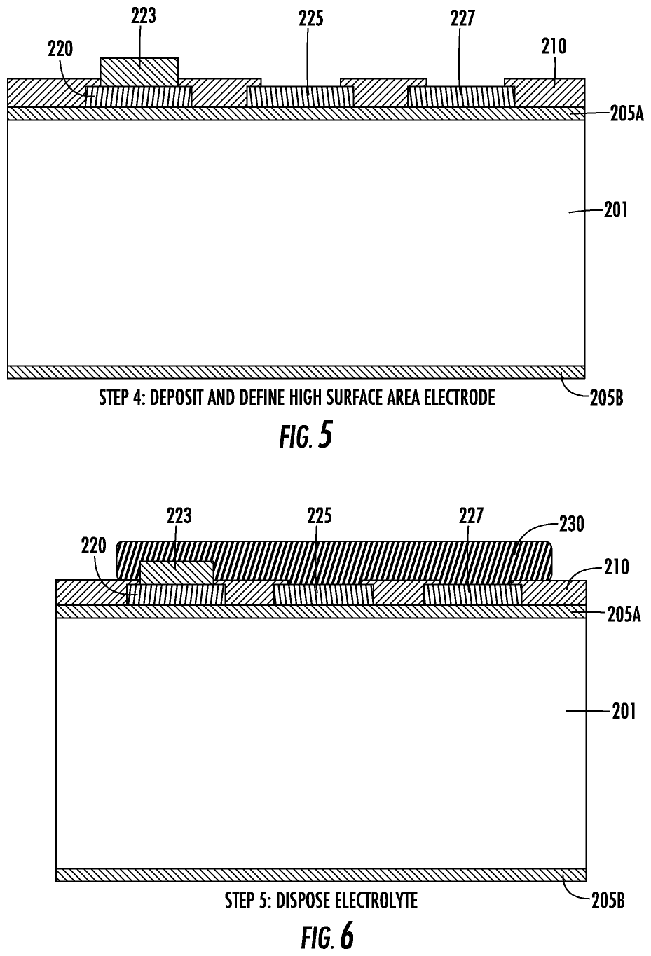

FIG. 6 illustrates a fifth step in the exemplary fabrication method. In Step 5, an electrolyte 230 is disposed over at least a portion of each electrode 225, 227 and the high surface area electrode 223. The electrolyte 230 can be a solid polymer electrolyte. The electrolyte 230 can be formed via a variety of printing technologies, such as ink jet printing, aerosol jet printing, or screen printing before singulation and subsequent packaging. Alternatively, the electrolyte 230 can be added during the packaging process after the substrate wafer of the MEMS-based electrochemical sensor is singulated.

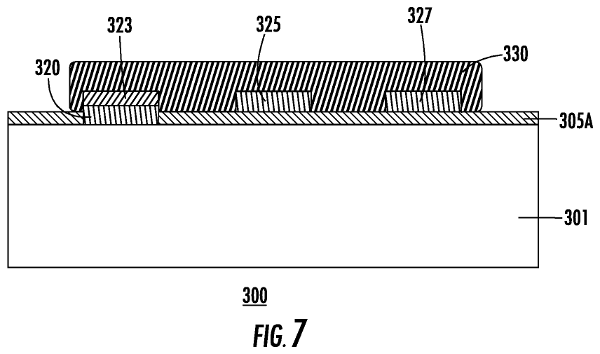

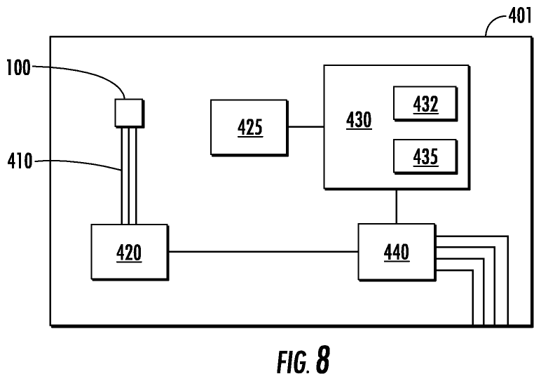

FIG. 7 depicts a cross-sectional elevation view of another exemplary MEMS-based electrochemical sensor 300 according to one embodiment. In the illustrated embodiment, the sensor 300 comprises a substrate 301 having a plurality of electrodes. The plurality of electrodes include a sensing electrode 320, a counter electrode 325, and a reference electrode 327. A first insulator/dielectric layer 305A is formed on a top surface of the substrate 301 such that at least a portion of electrodes 320, 325, 327 are not in contact with the substrate 301. Additionally, a high surface area electrode 323 is formed on an upper surface of the sensing electrode 320. The electrochemical sensor 300 further comprises an electrolyte 330, which is disposed over at least a portion of each electrode 323, 325, 327.

In some embodiments, the control circuitry and/or other processing circuitry (not shown in FIG. 1) for measuring the current or potential produced by the MEMS-based electrochemical sensor 100 may be formed on the same substrate of the MEMS sensor. Such a configuration may provide a more compact device and limit the potential for electrical noise to be introduced into the sensor output. In other embodiments, the MEMS-based electrochemical sensor 100 may be integrated with external circuitry designed for signal measurement or be directly integrated with existing circuitry within an instrument.

FIG. 8 illustrates the MEMS-based electrochemical sensor 100 in the context of exemplary circuitry 401. As will be appreciated from the description herein, the circuitry 401 may comprise an integrated circuit, printed circuit board, or the like. The circuitry 401 can be a separate component from the sensor, a portion of the packaging, or in some embodiments, an extension of the substrate such that the sensor 100 is formed on a single substrate that the other components are also disposed on. In this embodiment, the leads 410 may extend from pads electrically connected to the plurality of electrodes of the sensor 100 and contact various external circuitry such as a potentiostat circuitry 420, various sensing circuitry 425, operating and control circuitry 430, communication circuitry 440, and the like. The potentiostat circuitry 420 may control the voltage difference between the sensing electrode and the reference electrode of the sensor 100, and/or measure the current flow and/or voltage difference between the sensing electrode and the counter electrode of the sensor 100. The location of the potentiostat circuitry 420 at or near the sensor 100 may allow smaller currents to be detected while minimizing resistance, current loss, and electrical noise which would be inherent to longer electrical conductors. The various sensing circuitry 425 may comprise additional sensors, such as temperature and/or pressure sensors, which may allow for compensation of the outputs of the sensor 100 by taking compensation measurements at or near the sensor 100 itself. The operating and control circuitry 430 may comprise a processor 432 and a memory 435 for performing various calculations and control functions, which can be performed in software or hardware. The communication circuitry 440 may allow the overall sensor results or readings to be communicated to an external source, and can include both wired communications using for example contacts on the board, or wireless communications using a transceiver operating under a variety of communication protocols (e.g., WiFi, Bluetooth, etc.). In some embodiments, the sensor 100 can be a separate component that is electrically coupled to external operating circuitry.

It should be understood that the examples and embodiments described herein are for illustrative purposes only. Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. An electrochemical sensor comprising:
a substrate;
a plurality of electrodes disposed on the substrate;
a dielectric layer disposed on the substrate such that at least a portion of the plurality of electrodes are not in contact with the substrate;
a high surface area electrode disposed on the substrate and/or the dielectric layer; and
an electrolyte disposed over at least a portion of each of the high surface area electrode and the plurality of electrodes.

2. The electrochemical sensor of claim 1, wherein the high surface area electrode comprises a porous material.

3. The electrochemical sensor of claim 1, wherein the high surface area electrode comprises a fractal metal electrode.

4. The electrochemical sensor of claim 3, wherein the fractal metal electrode comprises a fractal platinum electrode.

5. The electrochemical sensor of claim 1, wherein the high surface area electrode is formed by electrochemical deposition.

6. The electrochemical sensor of claim 1, wherein the high surface area electrode is formed in a metal solvent mixture or a particle-free complex conductive ink.

7. The electrochemical sensor of claim 1, wherein the plurality of electrodes comprise a counter electrode and a reference electrode.

8. The electrochemical sensor of claim 1, wherein the plurality of electrodes comprise a sensing electrode disposed on the substrate and/or the dielectric layer and between the high surface area electrode and the substrate and/or the dielectric layer.

9. The electrochemical sensor of claim 1, wherein the high surface area electrode comprises at least one of gold, platinum, palladium, rhodium, or ruthenium.

10. The electrochemical sensor of claim 1, wherein the substrate comprises at least one of a porous silicon substrate, a porous alumina substrate, or a silicon substrate with micro-channels.

11. A method of forming an electrochemical sensor, the method comprising:
forming a plurality of electrodes on a substrate;
disposing a dielectric layer on the substrate such that at least a portion of the plurality of electrodes are not in contact with the substrate;
disposing a high surface area electrode on the substrate and/or the dielectric layer; and
disposing an electrolyte over at least a portion of each of the high surface area electrode and the plurality of electrodes.

12. The method of claim 11, wherein the high surface area electrode comprises a porous material.

13. The method of claim 11, wherein the high surface area electrode comprises a fractal metal electrode.

14. The method of claim 13, wherein the fractal metal electrode comprises a fractal platinum electrode.

15. The method of claim 11, wherein the high surface area electrode is formed by electrochemical deposition.

16. The method of claim 11, wherein the high surface area electrode is formed by printing one of an ink in a metal solvent mixture or a particle-free complex conductive ink.

17. The method of claim 11, wherein the plurality of electrodes comprise a counter electrode and a reference electrode.

18. The method of claim 11, wherein the plurality of electrodes comprise a sensing electrode disposed on the substrate and/or the dielectric layer and between the high surface area electrode and the substrate and/or the dielectric layer.

19. The method of claim 11, wherein the high surface area electrode comprises at least one of gold, platinum, palladium, rhodium, or ruthenium.

20. The method of claim 11, wherein the substrate comprises at least one of a porous silicon substrate, a porous alumina substrate, or a silicon substrate with micro-channels.
